(19) United States
(12) Patent Application Publication
(10) Pub. No.: US 2007/0057304 A1
(43) Pub. Date: Mar. 15, 2007

(54) Capacitor structure, memory cell and method for forming a capacitor structure

(75) Inventors: Tim Boescke, Dresden (DE); Matthias Goldbach, Dresden (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/223,145

(22) Filed: Sep. 12, 2005

(51) Int. Cl. H01L 29/94

(52) U.S. Cl. 257/301

(57) ABSTRACT

The present invention refers to a trench capacitor structure as it is used in memory cells, for example in memory cells of memory devices. Particularly, the capacitor structure may be used in a DRAM memory. Furthermore, the invention relates to a memory cell comprising a transistor and a capacitor with a trench capacitor structure arranged in a semiconductor substrate. Furthermore, the invention relates to a DRAM comprising a memory cell with a transistor and a capacitor, whereby the capacitor comprises a trench capacitor structure. Moreover, the invention relates to a method for forming a capacitor structure in a semiconductor substrate.

### TECHNICAL FIELD OF THE INVENTION

The present invention refers to a trench capacitor structure as it is used in memory cells, for example in memory cells of memory devices, and method for same.

### BACKGROUND OF THE INVENTION

Memory cells are, for example, used in semiconductor memories to store information on the charge state of a capacitor than can be accessed by a selection transistor. A memory cell includes a selection transistor and a capacitor in which the stored information is held. The capacitor is configured e.g. in the form of a trench capacitor. The embodiment of the memory cell with a trench capacitor offers the advantage that a relatively large volume of the trench capacitor can be disposed in the silicon substrate and the trench capacitor tapers in the direction of the surface of the substrate and adjoins the surface of the substrate with a relatively narrow cross-section. This offers the possibility of achieving a saving of the surface area required for the formation of the memory cell. Furthermore, the selection transistor is disposed on the surface of the substrate.

Limits are imposed on reducing the cross-section of the trench capacitor in the region of the surface since the conductivity of the trench filling in the region of the surface must have a predetermined value. Moreover, the configuration of an insulation collar is necessary to electrically insulate the trench filling from the substrate in the upper region, as well.

The article titled “Transistor on capacitor cell with quarter pitch layout”, by M. Sato et al., 2000 Symposion on VLSI Technology Digest of Technical Papers 2000 IEEE, pages 82 and 83, discloses a memory cell having a trench capacitor which has a lower wide region and an upper narrow region. The lower wide region is surrounded by a nitride film as an insulation layer. The upper end face of the wide region is covered by a thick silicon oxide layer. The narrow region is taken up to the surface of the substrate and is likewise insulated from the substrate by an insulation layer. The known embodiment of the trench capacitor has the disadvantage that the insulation layer insulating the narrow region has to be made relatively thick in order to avoid the formation of a parasitic field effect transistor in the substrate adjacent to the narrow region. Consequently, despite the embodiment of the narrow upper region of the trench filling, a relatively large surface region of the substrate surface is required for the formation of the trench capacitor. A memory cell with a trench capacitor of the generic type is known. The trench capacitor is configured in the form of a wide lower section and a narrow upper section. However, in this embodiment, as well, the narrow upper section has a relatively wide insulation collar. As a result, in this embodiment of the memory cell as well, a relatively large area is required for the formation of the memory cell with the trench capacitor.

U.S. patent application 2004/0032027 A1 describes a memory cell having a thin insulation collar and a memory module comprising such a memory cell. The memory cell comprises a substrate having a trench formed therein and a selection transistor having a terminal region. A capacitor is formed in the trench and has a trench filling with an upper region and a lower region. A first insulating layer is disposed above the trench filling and having a contact trench formed therein. The contact trench has a cross-section being smaller than the cross-section of the trench. A conductive filling is disposed in the contact trench and surrounded by the first insulating layer. The conductive filling connects the terminal region of the selection transistor to the trench capacitor. A second insulation layer is disposed surrounding the trench filling in the upper region and adjoining the first insulation layer. The second insulating layer has a second thickness being larger than the first thickness of the first insulation layer. The first thickness is formed for preventing a current flow, however, the formation of a parasitic field effect transistor being possible during operation of the memory cell. The described memory cell comprises a thin insulation collar. The collar constitutes a thin first insulating layer and adjacent to the collar, a wide second insulating layer is disposed in the substrate. Therefore, it may be achieved that no lateral current flow is established between the filling of the contact trench and the surrounding substrate. The relatively thick formation of the second insulating layer prevents an electrical conductive state of a second parasitic field effect transistor in the region of the second insulation layer. As a result, a leakage current rate of the trench capacitor is reduced overall. In principle, a first parasitic field effect transistor could form in the region of the first insulation layer and a second parasitic field effect transistor could form in the region of the second insulation layer. However, the two parasitic field effect transistors are connected in series and, with the second parasitic field effect transistor being turned off, a current flow from the trench capacitor into the surrounding substrate is prevented.

### SUMMARY OF THE INVENTION

The present invention refers to a trench capacitor structure as it is used in memory cells, for example in memory cells of memory devices. Particularly, the capacitor structure may be used in a DRAM memory. Furthermore, the invention relates to a memory cell comprising a transistor and a capacitor with a trench capacitor structure arranged in a semiconductor substrate. Furthermore, the invention relates to a DRAM comprising a memory cell with a transistor and a capacitor, whereby the capacitor comprises a trench capacitor structure. Moreover, the invention relates to a method for forming a capacitor structure in a semiconductor substrate.

Capacitor structures are used in different technical fields, for example in electronic circuits which store electrical charge and/or data information. Therefore, the invention may be used in any electrical or electronic circuits that use a capacitor structure.

The present invention provides a trench capacitor structure with a reduced leakage current which is achieved by an improved collar insulation.

Furthermore, the present invention provides a trench capacitor structure with an enhanced capacity.

Furthermore, the present invention provides a trench capacitor structure with a reduced series resistance and a reduced cell charging time.

In one embodiment of the present invention, there is a trench capacitor structure with a substrate comprising semiconductor material with a trench wherein the substrate comprises an upper, a middle and a lower section adjacent to the trench. A first electrode and a second electrode are arranged in the trench, wherein the first and the second electrode are separated and insulated by an insulating layer. The first electrode is arranged at least partly at a sidewall of the trench in the lower section. In the upper section, the second electrode is electrically connected with a first doped region of the substrate. Furthermore, a second doped region is disposed in the lower section of the substrate adjacent to the trench. The first electrode and the second doped region are conductively connected, wherein the insulating layer covers the sidewall of the trench insulating the substrate from the first and second electrode in the middle section. The first electrode extends from the lower section up to the middle section with an extended part. The extended part is arranged in a recess of the insulating layer. The first and second doped region have a higher electrical conductivity than the substrate and are doped with a polar dopant compared to the dopant of the substrate in the middle section adjacent to the trench.

In another embodiment of the present invention, a memory cell comprising a transistor and a capacitor with a trench capacitor structure arranged in a substrate. Additionally, the present invention is a DRAM comprising a memory cell with a transistor and a capacitor, whereby the capacitor comprises a trench capacitor structure arranged in a substrate.

In still another embodiment of the present invention, there is a method for forming a capacitor structure in a semiconductor substrate with a basic doping including:

providing a semiconductor substrate;

forming a trench in the substrate;

forming a first doped region in an upper section of the substrate adjacent to the trench;

forming a second doped region in a lower section of the substrate adjacent to the trench, whereby the dopants of the first and second regions are polar to a basic dopant of the substrate;

depositing an outer insulating layer in a middle section of the trench covering the substrate between the lower section and the upper section;

depositing a first conductive electrode layer in the lower section and at least partly in a lower part of the middle section, whereby at the lower section the first electrode layer is deposited on a sidewall of the trench in contact with the substrate, whereby in the middle section the electrode layer is deposited as an extended part on the insulating outer layer;

depositing an inner insulating layer on the first electrode layer and partly on the outer layer adjacent to an upper end rim of the first electrode layer;

filling up the trench with a second electrode layer, whereby the second electrode layer is connected to the first region.

The present invention is based on providing a trench capacitor structure, a memory cell with a trench capacitor structure, a DRAM with a memory cell comprising a trench capacitor structure and a method for forming a trench capacitor structure by means of a simple process and an improved collar insulation of the trench capacitor. This possibly allows for reduction of a concentration of dopants in a collar area in the substrate surrounding the upper section of the trench. Furthermore, a collar length may also be reduced. Additionally, the present invention is based on the idea of providing a trench capacitor structure with an enhanced capacity. Additionally, the present invention is based on the idea of reducing the charging time for the capacitor and of reducing the resistance of the electrical contact to the capacitor structure.

### BRIEF DESCRIPTION OF THE DRAWINGS

The present invention will be described in more detail below with reference to exemplary embodiments and the figures, in which:

FIG. 1 shows part of a DRAM showing a capacitor and a selection transistor in a substrate.

FIG. 2 shows a sectional view of a trench capacitor in a substrate.

FIG. 3 shows an equivalent electrical circuit of the trench capacitor of FIG. 2.

FIG. 4 shows another embodiment of a trench capacitor structure.

FIG. 5 shows a further embodiment of a trench capacitor structure.

FIGS. 6 to 8 show selected process steps of a method for forming a trench capacitor structure in a substrate.

### DETAILED DESCRIPTION OF THE INVENTION

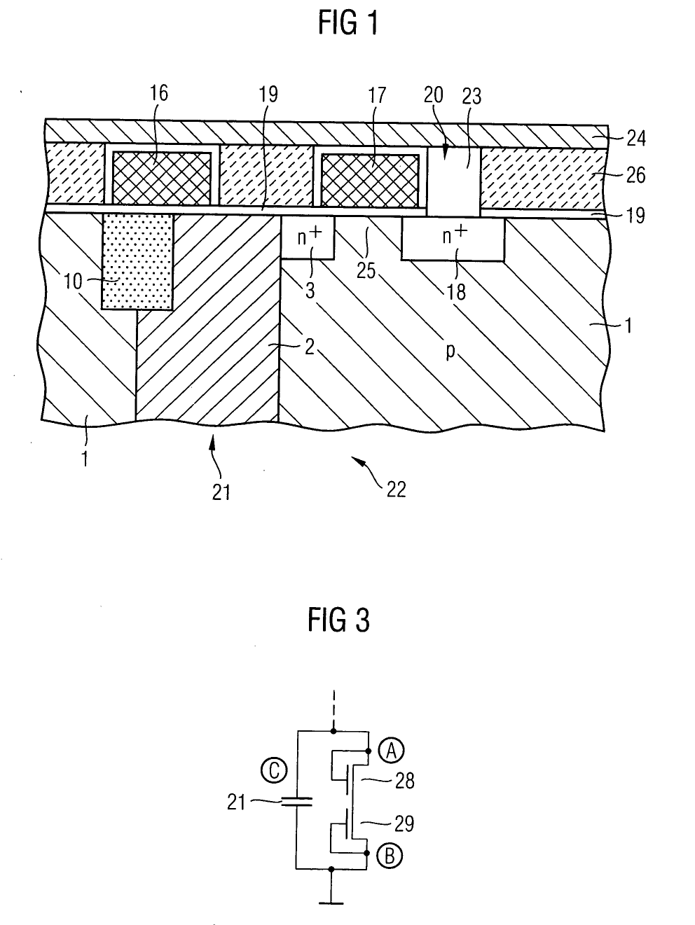

FIG. 1 shows a cross-section of a memory cell 22 with a capacitor 21 and a transistor 20. The memory cell 22 may be part of an electronic circuit, e.g. a random access memory or a DRAM. The capacitor 21 is arranged in a substrate 1 of a semiconductor material. The capacitor 21 comprises a trench structure with a trench 2 which is disposed in the substrate 1. The capacitor 21 is directly connected to a first doped region 3 which is arranged at an upper surface of the substrate 1 adjacent to the trench 2. The substrate 1 may comprise silicon which is positively doped and the first region 3 is negatively doped. The substrate 1 furthermore comprises a third doped region 18 which is disposed at a given distance to the first doped region 3 and is arranged at an upper surface of the substrate 1. The third doped region 18 is doped in the same manner as the first region 3. Between the first region 3 and the third region 18, a channel area 25 is disposed. The surface of the substrate 1 is covered by an insulating cover 19. On the insulating cover 19, a first word line 16 is arranged above the trench 2. Additionally, above the channel area 25 a second word line 17 is arranged on the insulating cover 19. The first and the second word line 16, 17 are insulated by a fill layer 26 covering the insulating cover 19 up to a height extending to the first and the second word line 16, 17. On the insulating fill layer 26, a bit line 24 is disposed. The bit line 24 is arranged in a perpendicular direction compared to the first and the second word line 16, 17. The first and the second word line 16, 17 are arranged in a parallel direction. Beside the second word line 17, a conductive contact 23 is disposed in the filler layer 26 connecting the third region 18 to the bit line 24. Depending on the voltage level in the second word line 17, the transistor 20 is switched into a conductive state electrically connecting the first and the third region 3, 18. The conductive transistor 20 therefore connects the capacitor 21 to the contact 23 and the bit line 24. Using this electrical connection, data may be written into the capacitor 21 of the memory cell 22 and/or read out from the capacitor memory cell 22.

For the doping of the substrate 1, a p-type dopant such as boron may be used. For the n-type region 3, 18, e.g. arsenic may be used. In order to form the insulating layers, silicon oxide, silicon nitride or silicon oxynitride may be used.

Additionally, an STI insulation region 10 is disposed adjacent to the trench 2 for insulating an upper end region of the trench 2 from a neighboured active area of another transistor which is part of another memory cell. Depending on the embodiment, the substrate 1 may be negatively and the first and third regions 3, 18 may be positively doped.

FIG. 2 depicts a detailed view of the capacitor structure which is arranged in the trench 2 and the substrate 1. The trench 2 has the shape of a cylinder with a rounded end phase at a bottom. At a lower section 11 of the trench 2, a second doped region 4 is disposed in the substrate 1 surrounding the trench 2. The second region 4 is negatively doped as well as the first region 3. The second region 4 borders directly at the sidewall of the trench 2. The second region 4 extends from the bottom of trench 2 up to a border line 27, that separates the lower from a middle section 11, 12.

Normally in a substrate 1, a lot of memory cells 22 with trenches 2 and capacitors 21 are disposed whereby the trench capacitor structures are identical and the second regions 4 of the different memory cells 22 are electrically connected by means of a common buried plate that is arranged in the substrate.

At the middle section 12 and an upper section 13 of the trench 2, an outer insulating layer 8 is disposed at the sidewall of the trench 2. The outer insulating layer 8 constitutes a collar rim which insulates the substrate 1 in the middle and upper section 12, 13 from the trench 2. The outer layer 8 extends from the lower section 11 up to the surface of the substrate 1, whereby the outer layer stops at an STI insulation 10 that is arranged in the substrate 1. Additionally, the outer layer 8 has an opening at the first region 3, whereby the first region 3 is in direct contact with the second electrode 6. The outer layer 8 covers an upper ring part of the second region 4 with a lower part. Additionally, the outer layer 8 covers a lower part of the first region 3. The STI insulation 10 surrounds the upper end of the trench 2, insulating the upper region of the trench 2 from the substrate 1 beside a direct contact area in which the first region 3 borders directly at the trench 2.

In the lower section 11, the first electrode 5 covers as a thin layer a bottom and the lower section of the sidewalls of the trench 2 up to the outer layer 8. Additionally, the first electrode 5 extends up to the middle section 12 with an extended part 14. The extended part 14 of the first electrode 5 is disposed at an inner face of the outer layer 8. An inner face of the first electrode 5 is completely covered with an inner insulating layer 9 extending from the bottom of trench 2 up to the upper section 13 of the trench 2 and at least partly covering a ring face of the outer layer 8 at the upper end rim of the extended part 14. An inner region of the trench 2 is filled up with the second electrode 6 which is in direct contact with the first region 3. An outer surface of the second electrode 6 is insulated by the STI insulation 10 and the inner insulating layer 9. The first electrode 5 may comprise a metal material or any other electrically conductive material. The inner insulating layer 9 may comprise a dielectric material, e.g. a high k dielectric material. It is possible to use dielectric material with a high dielectric constant k such as e.g. tantalum oxide, titanium oxide, barium strontium titanate.

The outer insulating layer 8 may comprise aluminium oxide, silicon oxide or a composition of aluminium, silicon and hydrogen. The outer insulating layer 8 may also comprise low k-material for example silicon boron nitride, silicon carbon oxynitride or fluorinated silicon oxide. The first and the second electrodes 5, 6 may e.g. comprise one of the material combination TiN (titanium nitride), TaN (tantalum nitride), NbN (niobium nitride), TiXN, TaXN, NbXN, whereby X defines one element of the group silicon, hafnium, aluminium, carbon. Additionally, the first and the second electrodes may comprise carbon. The second electrode 6 may be constituted by negatively doped polysilicon.

Ideally, the first and the second electrodes should have a high work function higher than 4.5 eV.

A main feature of the capacitor structure shown in FIG. 2 is that the first electrode 5 extends over the outer layer 8 with the extended part 14. In the region of the extended part 14, the first electrode 5 is arranged in a ring layer at the middle section 12 arranged at the height of a normally positively doped region of the substrate 1.

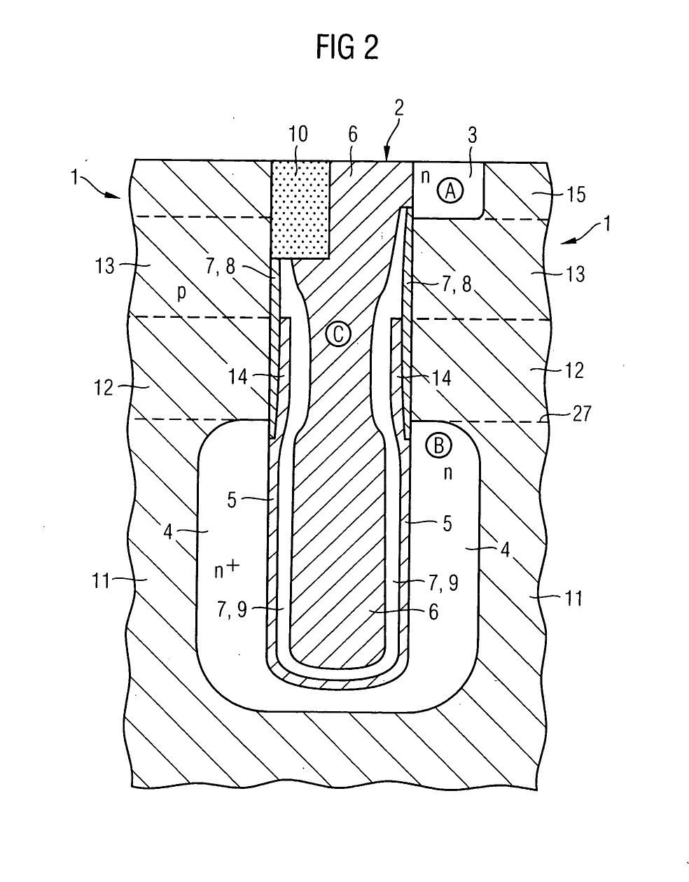

FIG. 3 depicts an equivalent electrical circuit according to the capacitor structure of FIG. 2. The second electrode 6 is marked with a letter C, the first region 3 is marked with a letter A and the second region 4 is marked with a letter B. The trench capacitor structure of FIG. 2 forms a capacitor 21 which is arranged in parallel with two parasitic n-FETs which are split into two controlled p-n-junctions. Therefore, during normal operation of the capacitor 21, the two n-FETs are normally off. The first parasitic transistor 28 is formed by the first region 3 and the second region 4 as source and drain and the upper section 13 of the substrate 1 adjacent to the trench 2 as a channel area. Additionally, the gate of the first parasitic transistor 28 is constituted by the second electrode 6 in the upper section 13.

A second parasitic transistor 29 includes the second region 4 and the first region 3 as source and drain and the middle section 12 of the substrate 1 adjacent to the outer layer 8 as channel area. A gate contact of the second parasitic transistor 29 consists of the extended part 14 of the first electrode 5. Thus, the first parasitic transistor 28 comprises a p-n-junction at the border between the first region 3 and the substrate 1. The second parasitic transistor 29 comprises a p-n-junction at the border between the second region 4 and the substrate 1. The two p-n-junctions of the first and the second parasitic transistor 28, 29 are normally off, i.e. no parasitic current flows from the first region 3 to the second region 4. Due to these two parasitic transistors 28, 29, the thickness of the outer layer 8 can be as low as a leakage current through the outer layer 8 can be tolerated. This is usually a much lower thickness than that required for an insulated collar of a trench capacitor in the state of the art.

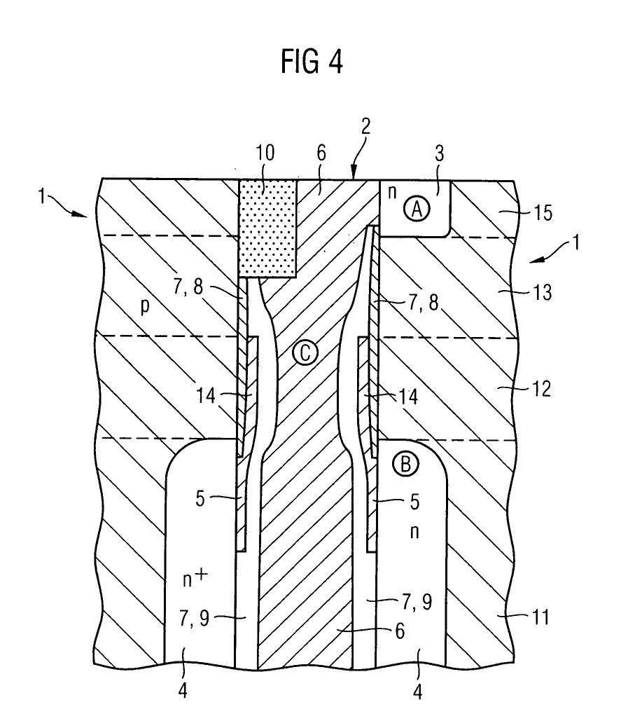

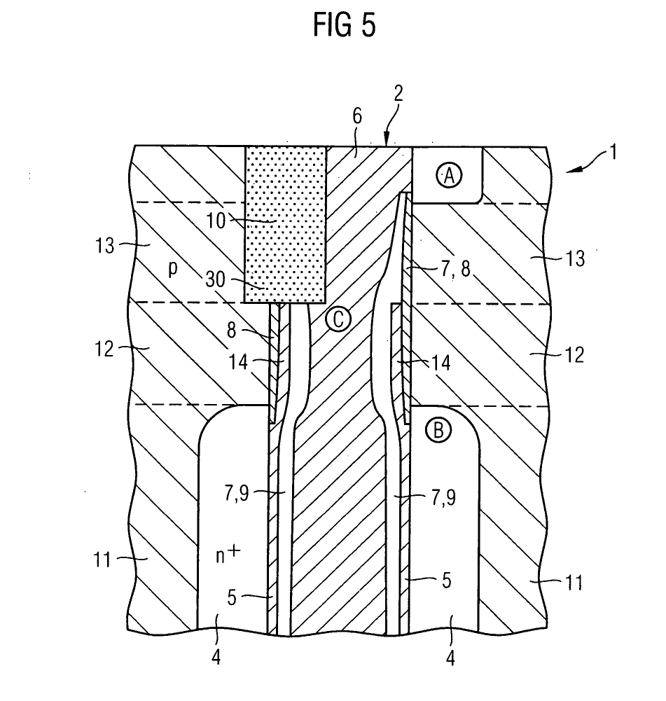

FIG. 4 depicts another embodiment of the invention, differing from the embodiment of FIG. 2 by the shape of the first electrode 5. In contrast to the embodiment of FIG. 2, the first electrode 5 of FIG. 4 comprises the shape of a sleeve covering an upper part of the lower section 11 and covering a lower part of the outer layer 8 with the extended part 14. Additionally, the inner layer 9 covers the whole surface of the first electrode 5 and a lower part of the sidewall of the trench in the lower section. The inner part of the trench is filled up with the second electrode 6.

FIG. 5 depicts another embodiment of the invention, in which the STI insulation 10 extends from an upper surface of the substrate 1 down to the middle section 12. The extended part 14 of the first electrode 5 borders directly at the STI insulation 10. The other features of this embodiments conform to the embodiment of FIG. 2.

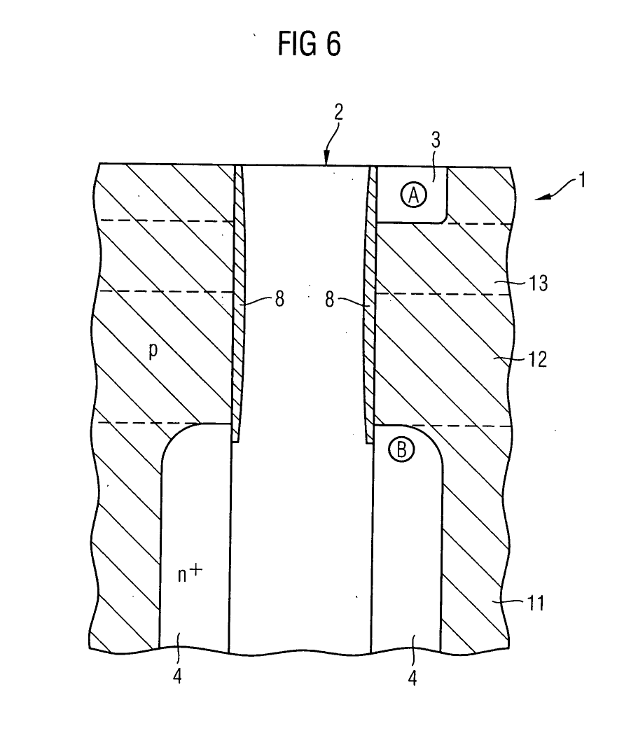

Using the FIGS. 6 to 8, a simplified process is explained for manufacturing the trench capacitor structure. FIG. 6 depicts a process situation in which the substrate 1, the first region 3 and the second region 4 have been formed and the substrate 1 may comprise silicon doped with boron with 2*10¹⁶ per cm³. The negatively doped first and second region 3, 4 may be formed by a gas phase doping for the second region 4 and by a plate implant process for the first region 3. The trench 2 is etched into the substrate 1. Additionally, the outer layer 8 is deposited in a sleeve layer which extends from the surface of the substrate 1 down to the lower section 11 and covers at least an upper rim part of the second region 4. The outer layer 8 may be deposited by a chemical vapor deposition process.

Depending on the used process for depositing the outer layer 8 constituting an insulating collar, a doping mask may be provided covering the lower part of the lower section 11 of the sidewall of the trench 2 which should not be covered by the outer layer 8.

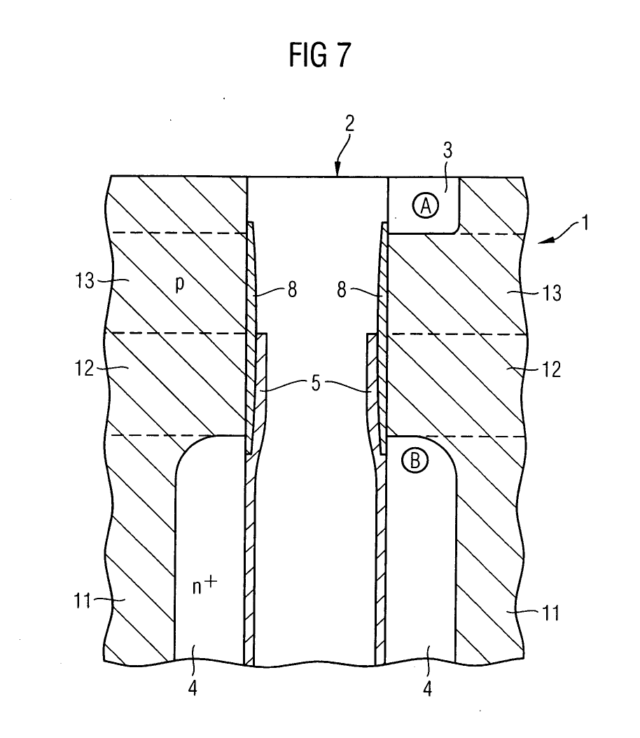

After this process, the first electrode 5 is deposited on the trench sidewall and the trench bottom. Additionally, the outer layer 8 may be recessed in an upper ring region adjacent to the surface of the substrate 1 as shown in FIG. 7.

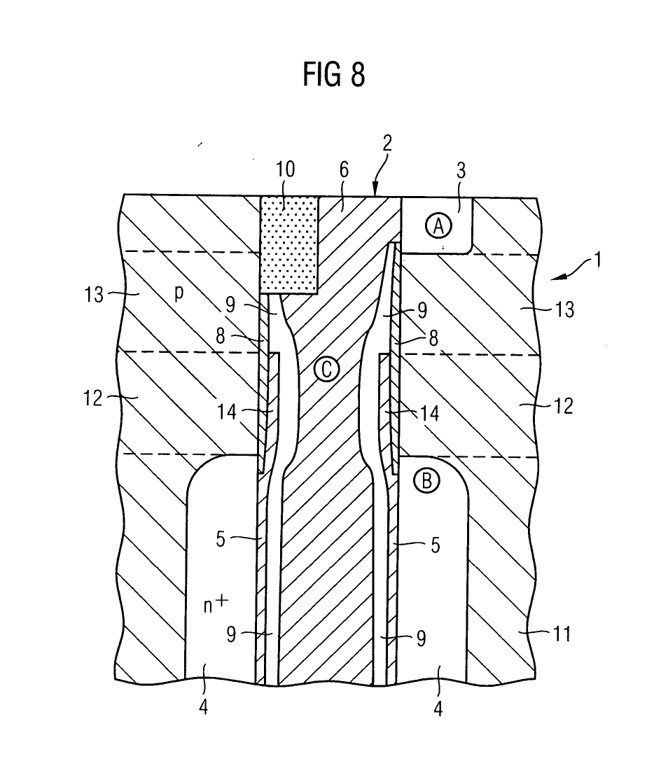

In a further process step, the inner layer 9 comprising dielectric material is deposited on the surface of the outer layer 8 and the surface of the first electrode 5. Then the trench 2 is filled up with the second electrode 6 and the STI insulation 10 is formed in an upper ring section surrounding the trench 2, whereby a contacting face between the second electrode 6 and the first region 3 is kept free from the STI insulation 10. This is shown in FIG. 8.

The embodiments of FIG. 4 and FIG. 5 are manufactured according to the same process, whereby according to the embodiment of FIG. 4 the first electrode 5 is deposited as a conductive ring layer covering a lower part of the outer layer 8 and an upper part of the lower section 11 of the sidewall of the trench 2 which borders at the second region 4. The lower part of the trench 2 is covered by the inner layer 9 which preferably comprises dielectric material with a high dielectric constant k.

The embodiment of FIG. 5 is formed according to the process explained with reference to FIG. 6 to 8, whereby the STI insulation 10 is fabricated with a larger extension down to the first electrode 5 and with a larger extension to the substrate 1. The STI insulation 10 of FIG. 5 extends from the trench 2 into the substrate 1 with an edge area 30 projecting into the substrate 1 in a horizontal direction. The edge area 30 improves the insulating function of the STI insulation 10 adjacent to the first electrode 5 bordering at the STI insulation 10.

A basic idea of the invention is to tune the effective work function of the gate of the parasitic device, i.e. the first and the second parasitic transistor 27, 28 is tuned in such a way that the flat band voltage is positive. This measurement allows for a reduction of the thickness of the collar oxide which includes the insulating layer 7 comprising the outer and/or the inner layer 8, 9. The second main idea is to extend the metal of the first electrode 5 partially over the outer layer 8. In doing so, the parasitic collar device is split into the two separately controlled parasitic transistors 28, 29. Since gate and source of the parasitic transistors are directly connected, the voltage from gate to source is always 0 Volt and the parasitic transistors 27, 28 are always turned off.

These modifications allow for the use of a very thin outer layer 8 with a thickness smaller than 5 nm. The combination of the shielded collar concept and work function engineering of the collar device is combined to create an intrinsically turned off collar device in the substrate 1 adjacent to the trench. This results in a more efficient collar insulation than provided in the state of the art and allows for a significant reduction of the thickness of the insulating collar. Based on this idea, a simplified integration flow process is proposed which does not require the creation of a separate, thick collar oxide.

### REFERENCE LIST

1 substrate
2 trench
3 first region
4 second region
first electrode
6 second electrode
7 insulating layer
8 outer layer
9 inner layer
10 STI insulation
11 lower section
12 middle section
13 upper section
14 extended part
16 first word line
17 second word line
18 third region
19 insulating cover
20 transistor
21 capacitor
22 memory cell
23 contact
24 bit line
25 channel area
26 fill layer
27 border line
28 first parasitic transistor
29 second parasitic transistor
30 edge area

What is claimed is:

1. A trench capacitor structure, comprising:
a substrate having semiconductor material with a trench, the substrate comprising an upper, a middle and a lower section adjacent to the trench; and
a first electrode and a second electrode arranged in the trench, wherein
the first and the second electrode are separated and insulated by an insulating layer,
the first electrode is arranged at least partly at a sidewall of the trench in the lower section,
the second electrode is electrically connected in the upper section with a first doped region of the substrate, a second doped region is disposed in the lower section of the substrate adjacent to the trench,
the second electrode and the second doped region are conductively connected,
the insulating layer covers in the upper and the middle section the sidewall of the trench insulating the substrate from the first and second electrode,
the second electrode extends with an extended part from the lower section up to the middle section, whereby the extended part is arranged in a recess of the insulating layer, and
the first and second doped region have a higher electrical conductivity than the substrate and are doped with a polar dopant compared to the dopant of the substrate in the middle section adjacent to the trench.

2. The trench capacitor structure of claim 1, wherein the recess comprises an inner and an outer layer of the insulating layer, the inner layer is arranged between the extended part of the first electrode and the second electrode, the outer layer is arranged between the trench sidewall and the first electrode, and the outer and the inner layer comprise different materials.

3. The trench capacitor structure according to claim 1, wherein the insulating layer comprises at least partly a dielectric material.

4. The trench capacitor structure of claim 2, wherein the inner layer comprises a dielectric material.

5. The trench capacitor structure of claim 1, wherein the insulating layer comprises at an upper section of the substrate an STI insulating region.

6. The trench capacitor structure of claim 5, wherein the recess of the insulating layer extends up to the STI insulating region.

7. The trench capacitor structure of claim 2, wherein the second layer is arranged between the first and second electrode and covers an inner surface of the first electrode.

8. The trench capacitor structure of claim 1, wherein the first electrode has a shape of a sleeve that extends from an upper rim of the lower section to the middle section with an extended part, wherein an inner face of the first electrode is covered by the insulating layer that covers the sidewall of the trench at the lower section and at the bottom.

9. The trench capacitor structure of claim 2, wherein the outer layer comprises Al₂O₃.

10. The trench capacitor structure of claim 2, wherein the outer layer comprises silicon oxide.

11. The trench capacitor structure of claim 2, wherein the second electrode comprises polysilicon and the outer layer comprises Al₂O₃.

12. The trench capacitor structure of claim 2, wherein the first or second electrode comprise TiXN, whereby X constitutes an element of a group of elements comprising Si, Hf, Al and C.

13. The trench capacitor structure of claim 2, wherein the first or second electrode comprise TaXN, whereby X constitutes an element of a group comprising Si, Hf, Al and C.

14. The trench capacitor structure of claim 2, wherein the first or second electrode comprise NbXN, whereby X constitutes one element of a group comprising Si, Hf, Al and C.

15. The trench capacitor structure of claim 2, wherein the first or second electrode comprise TiN.

16. The trench capacitor structure of claim 2, wherein the first or second electrode comprise TaN.

17. Trench capacitor structure of claim 2, wherein the first or second electrode comprise NbN.

18. The trench capacitor structure of claim 2, wherein the outer layer covers the middle section of the sidewall of the trench.

19. A memory cell, comprising:
a transistor and a capacitor with a trench capacitor structure arranged in a substrate comprising semiconductor material with a trench,
the substrate comprises
an upper, a middle and a lower section adjacent to the trench,
a first electrode and a second electrode are arranged in the trench, wherein
the first and the second electrode are separated and insulated by an insulating layer,
the first electrode is arranged at least partly at a sidewall of the trench in the lower section,
the second electrode is electrically connected in the upper section with a first doped region of the substrate,
a second doped region is disposed in the lower section of the substrate adjacent to the trench,
the second electrode and the second doped region are conductively connected,
the insulating layer covers in the upper and the middle section the sidewall of the trench insulating the substrate from the first and second electrode,
the second electrode extends with an extended part from the lower section up to the middle section, whereby the extended part is arranged in a recess of the insulating layer, and
the first and second doped region have a higher electrical conductivity than the substrate and are doped with a polar dopant compared to the dopant of the substrate in the middle section adjacent to the trench.

20. A DRAM, comprising:
a memory cell comprising
a transistor, a capacitor and a word line disposed for switching the transistor; and
a bit line disposed for reading out or writing in data from the memory cell, wherein
the capacitor comprises a trench capacitor structure arranged in a substrate comprising semiconductor material with a trench,
the substrate comprises an upper, a middle and a lower section adjacent to the trench,
a first electrode and a second electrode are arranged in the trench,
the first and the second electrode are separated and insulated by an insulating layer,
the first electrode is arranged at least partly at a sidewall of the trench in the lower section,
the second electrode is electrically connected in the upper section with a first doped region of the substrate,
a second doped region is disposed in the lower section of the substrate adjacent to the trench,
the second electrode and the second doped region are conductively connected,
the insulating layer covers in the upper and the middle section the sidewall of the trench insulating the substrate from the first and second electrode,
the second electrode extends with an extended part from the lower section up to the middle section, whereby the extended part is arranged in a recess of the insulating layer, and
the first and second doped region have a higher electrical conductivity than the substrate and are doped with a polar dopant compared to the dopant of the substrate in the middle section adjacent to the trench.

21. A method for forming a capacitor structure in a semiconductor substrate with a basic doping, comprising:
providing a semiconductor substrate;
forming a trench in the substrate;
forming a first doped region in an upper section of the substrate adjacent to the trench;
forming a second doped region in a lower section of the substrate adjacent to the trench, whereby the dopants of the first and second regions are polar to a dopant of the basic doping of the substrate;
depositing an outer insulating layer in a middle section of the trench covering the substrate between the lower section and the upper section;
depositing a first conductive electrode layer in the lower section and at least partly in a lower part of the middle section, whereby at the lower section the electrode layer is deposited on a sidewall of the trench, whereby in the middle section the electrode layer is deposited as an extended part on the insulating outer layer;
depositing an inner insulating layer on the first electrode layer and partly on the outer layer adjacent to an upper end rim of the electrode layer; and
filling up the trench with a second electrode layer.

22. The method according to claim 21, wherein the first electrode layer is deposited on a lower ring section of the outer layer and on an upper ring section of the lower section of the trench sidewall with a shape of a cylindrical sleeve, and the inner insulating layer is deposited on the whole inner face of the first electrode layer insulating the first electrode layer from the filling of the trench.
